(19) United States
(12) Patent Application Publication
(10) Pub. No.: US 2022/0085317 A1
(43) Pub. Date: Mar. 17, 2022

(54) ORGANIC LIGHT-EMITTING DEVICE AND DISPLAY PANEL

(71) Applicant: KUNSHAN GO-VISIONOX OPTO-ELECTRONICS CO., LTD, Kunshan (CN)

(72) Inventors: Hui PANG, Kunshan (CN); Bin LIU, Kunshan (CN); Mengzhen LI, Kunshan (CN)

(73) Assignee: KUNSHAN GO-VISIONOX OPTO-ELECTRONICS CO., LTD, Kunshan (CN)

(21) Appl. No.: 17/536,603

(22) Filed: Nov. 29, 2021

Related U.S. Application Data
(63) Continuation of application No. PCT/CN2020/099080, filed on Jun. 30, 2020.

(30) Foreign Application Priority Data
Oct. 18, 2019 (CN) 201910994670.2

(51) Int. Cl. H01L 51/50

(52) U.S. Cl. CPC H01L 51/5092; H01L 51/5056; H01L 51/5072

(57) ABSTRACT

Provided are an organic light-emitting device and a display panel. The organic light-emitting device includes a first electrode, a second electrode, an electron injection layer and a light-emitting material layer which are disposed between the first electrode and the second electrode. A material of the electron injection layer includes ytterbium and further includes at least one of lithium fluoride, 8-hydroxyquinolinolato-lithium, lithium nitride, cesium fluoride, or cesium carbonate.

This application is a Continuation Application of International Patent Application No. PCT/CN2020/099080, filed Jun. 30, 2020, which claims priority to Chinese patent application No. 201910994670.2 filed with the CNIPA on Oct. 18, 2019, disclosure of which is incorporated herein by reference in their entireties.

### TECHNICAL FIELD

The present application relates to the field of display technologies in particular, to an organic light-emitting device and a display panel.

### BACKGROUND

With the development of display techniques, an organic light-emitting display panel has been widely used due to advantages such as high response amplitude, high color purity, wide viewing angle, foldability, or low energy consumption.

The organic light-emitting display panel includes a plurality of organic light-emitting devices which have the defect of short lifetime.

### SUMMARY

The present application provides an organic light-emitting device and a display panel to prolong service life of the organic light-emitting device and service life of the display panel.

In a first aspect, provided is an organic light-emitting device, including a first electrode, a second electrode, an electron injection layer disposed between the first electrode and the second electrode and a light-emitting material layer disposed between the first electrode and the second electrode. The electron injection layer is disposed between the second electrode and the light-emitting material layer.

A material of the electron injection layer includes ytterbium and further includes at least one of lithium fluoride, 8-hydroxyquinolinolato-lithium, lithium nitride, cesium fluoride, and cesium carbonate.

In a second aspect, further provided is a display panel, including a plurality of organic light-emitting devices provided in the first aspect.

### BRIEF DESCRIPTION OF DRAWINGS

FIG. 1 is a structural diagram of an organic light-emitting device according to an embodiment of the present application;

FIG. 2 is a structural diagram of another organic light-emitting device according to an embodiment of the present application;

FIG. 3 is a structural diagram of another organic light-emitting device according to an embodiment of the present application;

FIG. 4 is a structural diagram of another organic light-emitting device according to an embodiment of the present application;

FIG. 5 is a structural diagram of another organic light-emitting device according to an embodiment of the present application; and

FIG. 6 is a structural diagram of a display panel according to an embodiment of the present application.

### DETAILED DESCRIPTION

The present application will be described below in conjunction with drawings and embodiments. The embodiments described below are merely intended to explain but not to limit the present application. Only part, not all, of structures related to the present application are illustrated in the drawings.

As described in the background, organic light-emitting devices have defects of short lifetime and low light-emitting efficiency. According to the research of the applicant, the reason for the above problems is described below. Organic-light emitting devices typically include an electron injection layer, and in order to ensure the electron injection capability of the electron injection layer, the material of the electron injection layer in the organic light-emitting device typically adopts a metal material with a lower work function. However, the metal material of the electron injection layer in the organic light-emitting device of related art is typically relatively active in chemical properties and is easily oxidized. Therefore, with the use of the organic-light emitting device, the electron injection capability decreases rapidly after the material of the electron injection layer is oxidized, and the service life of the organic light-emitting device is relatively short.

This embodiment provides an organic light-emitting device. FIG. 1 is a structural diagram of an organic light-emitting device according to an embodiment of the present application. Referring to FIG. 1, the organic light-emitting device includes a first electrode 110, a second electrode 120, an electron injection layer 130 disposed between the first electrode 110 and the second electrode 120, and a light-emitting material layer 140 disposed between the first electrode 110 and the second electrode 120. The electron injection layer 130 is disposed between the second electrode 120 and the light-emitting material layer 140. A material of the electron injection layer 130 includes ytterbium and further includes at least one of lithium fluoride, 8-hydroxyquinolinolato-lithium, lithium nitride, cesium fluoride, and cesium carbonate.

In this embodiment, the chemical formula of the 8-hydroxyquinolinolato-lithium is as follows:

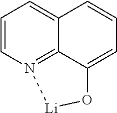

In one embodiment, the first electrode 110 is an anode of the organic light-emitting device, and the second electrode 120 is a cathode of the organic light-emitting device. The organic light-emitting device may be applied to an organic light-emitting display panel, and the organic light-emitting display panel may be of a top light-emitting type or a bottom light-emitting type. When the organic light-emitting device is applied to the organic light-emitting display panel of the top light-emitting type, the first electrode 110, that is, the anode, is a reflective electrode, that is, an opaque electrode, and the anode may adopt a three-layer structure. A first layer and a third layer disposed on two sides of the anode may be metal oxides such as indium tin oxide (ITO), indium zinc oxide (IZO), or aluminum zinc oxide (AZO), and a second layer in the middle of the anode may be the metal (such as silver or copper). The second electrode 120, that is, the cathode, may be an ITO light-transmitting electrode or a magnesium-silver alloy. When the organic light-emitting device is applied to the organic light-emitting display panel of the bottom light-emitting type, the first electrode 110, that is, the anode, is a light-transmitting electrode, and the second electrode 120, that is, the cathode, is an opaque electrode and serves as the reflective electrode. The cathode is made of magnalium alloy or the like and the anode may be made of the ITO.

Still referring to FIG. 1, the organic light-emitting device further includes the light-emitting material layer 140 disposed between the first electrode 110 and the second electrode 120. A light-emitting color of the organic light-emitting device is related to a light-emitting material of the light-emitting material layer 140. Different organic light-emitting devices can emit light of different colors. For example, the organic light-emitting device includes an organic light-emitting device that emits red light, an organic light-emitting device that emits green light, and an organic light-emitting device that emits blue light.

The electron injection layer 130 is disposed between the second electrode 120 and the light-emitting material layer 140, thereby ensuring that electrons supplied from the second electrode 120 can be effectively injected into the light-emitting material layer 140. In the display panel provided by this embodiment, the electron injection layer 130 includes the metal material ytterbium. The metal material ytterbium has a relatively low work function and a strong electron injection capability so that electrons can be more easily injected into the light-emitting material layer 140, thereby ensuring that the organic light-emitting device can normally emit light. However, the metal material ytterbium is active in chemical properties and easy to be oxidized. The material of the electron injection layer 130 further includes at least one of the lithium fluoride, the 8-hydroxyquinolinolato-lithium, the lithium nitride, the cesium fluoride, and the cesium carbonate. The lithium fluoride, the 8-hydroxyquinolinolato-lithium, the lithium nitride, the cesium fluoride, and the cesium carbonate also have a relatively low work function so that the electron injection capability can be further improved. Moreover, the lithium fluoride, the 8-hydroxyquinolinolato-lithium, the lithium nitride, the cesium fluoride, and the cesium carbonate are stable in the chemical properties. Therefore, the material of the electron injection layer 130 further includes at least one of the lithium fluoride, the 8-hydroxyquinolinolato-lithium, the lithium nitride, the cesium fluoride, and the cesium carbonate so that the oxidation of the metal material ytterbium can be slowed down and thus a rate of decline of the electron injection capability of the electron injection layer 130 is reduced. That is, in this manner, the electron injection layer 130 maintains a higher electron injection capability for a long time, thereby prolonging the service life of the organic light-emitting device.

The organic light-emitting device provided by the embodiment includes the first electrode, the second electrode, the electron injection layer disposed between the first electrode and the second electrode, and the light-emitting material layer disposed between the first electrode and the second electrode. The material of the electron injection layer includes the ytterbium and further includes at least one of the lithium fluoride, the 8-hydroxyquinolinolato-lithium, the lithium nitride, the cesium fluoride, and the cesium carbonate. Since the metallic ytterbium has a relatively low work function and active chemical property, the electron injection layer has a higher electron injection capability. Moreover, since the lithium fluoride, the 8-hydroxyquinolinolato-lithium, the lithium nitride, the cesium fluoride, and the cesium carbonate are stable in the chemical properties, the oxidation of the metallic ytterbium can be slowed down and thus the rate of decline of the electron injection capability of the electron injection layer is reduced. That is, in this manner, the electron injection layer maintains the higher electron injection capability for a long time, thereby prolonging the service life of the organic light-emitting device.

Still referring to FIG. 1, on the basis of the above-mentioned solution, in one embodiment, the electron injection layer 130 is a single layer structure.

In this embodiment, when the electron injection layer 130 is the single layer structure, the electron injection layer 130 is formed by doping the ytterbium and at least one of the lithium fluoride, the 8-hydroxyquinolinolato-lithium, the lithium nitride, the cesium fluoride, and the cesium carbonate, or the electron injection layer 130 may also include the ytterbium, at least one of the lithium fluoride, the 8-hydroxyquinolinolato-lithium, the lithium nitride, the cesium fluoride, and the cesium carbonate, and other materials. The electron injection layer 130 is provided as a single-layer structure such that the electron injection layer 130 of the single-layer structure includes both the ytterbium and at least one of the lithium fluoride, the 8-hydroxyquinolinolato-lithium, the lithium nitride, the cesium fluoride, and the cesium carbonate. In this manner, at least one of the lithium fluoride, the 8-hydroxyquinolinolato-lithium, the lithium nitride, the cesium fluoride, and the cesium carbonate is provided around the ytterbium. Moreover, the lithium fluoride, the 8-hydroxyquinolinolato-lithium, the lithium nitride, the cesium fluoride, and the cesium carbonate are stable in chemical properties so that the material with stable chemical properties wraps the ytterbium with active chemical properties. In this manner, the ytterbium is not easy to contact the oxygen and the oxidation of the ytterbium is further inhibited so that the electron injection layer 130 maintains the higher electron injection capability. Moreover, the electron injection layer 130 is provided as the single-layer structure such that the electron injection layer 130 can has a relatively thin thickness, thereby facilitating the thinning of the organic light-emitting device; and when the organic light-emitting device is applied to the organic light-emitting display panel, the thinning of the organic light-emitting display panel is facilitated.

On the basis of the above-mentioned solution, in one embodiment, a mass ratio of the ytterbium in the material of the electron injection layer 130 to the at least one of the lithium fluoride, the 8-hydroxyquinolinolato-lithium, the lithium nitride, the cesium fluoride, or the cesium carbonate in the material of the electron injection layer 130 ranges from 1:10 to 10:1.

In this embodiment, the mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 refers to a ratio of a mass of the ytterbium in the material of the electron injection layer 130 to a mass of the at least one of the lithium fluoride, the 8-hydroxyquinolinolato-lithium, the lithium nitride, the cesium fluoride, and the cesium carbonate in the material of the electron injection layer 130. The mass of the at least one of the lithium fluoride, the 8-hydroxyquinolinolato-lithium, the lithium nitride, the cesium fluoride, and the cesium carbonate refers to a total mass of the lithium fluoride, the 8-hydroxyquinolinolato-lithium, the lithium nitride, the cesium fluoride, and the cesium carbonate included in the material of the electron injection layer 130.

In this embodiment, the ytterbium has a relatively strong electron injection capacity, and the lithium fluoride, the 8-hydroxyquinolinolato-lithium, the lithium nitride, the cesium fluoride, and the cesium carbonate have a relatively weak electron injection capacity compared with the ytterbium. Therefore, in order to ensure the electron injection capacity of the electron injection layer 130, a proportion of the ytterbium in the electron injection layer 130 cannot be too little. However, since the ytterbium is active in chemical properties and the lithium fluoride, the 8-hydroxyquinolinolato-lithium, the lithium nitride, the cesium fluoride, and the cesium carbonate are relatively stable in chemical properties, in order to inhibit the oxidation of the ytterbium in the electron injection layer 130, a proportion of at least one of the lithium fluoride, the 8-hydroxyquinolinolato-lithium, the lithium nitride, the cesium fluoride, and the cesium carbonate in the electron injection layer 130 cannot be too little. The mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 is set to range from 1:10 to 10:1 such that the ytterbium in the electron injection layer 130 is not too little and the at least one of the lithium fluoride, the 8-hydroxyquinolinolato-lithium, the lithium nitride, the cesium fluoride, and the cesium carbonate in the electron injection layer 130 is not too little. Therefore, the electron injection capability of the electron injection layer 130 can be ensured, and the oxidation of the ytterbium in the electron injection layer 130 can be inhibited, thereby prolonging the service life of the organic light-emitting device.

On the basis of the above-mentioned solution, in one embodiment, the mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 is 1:1.

Table 1 shows two groups of test results obtained from a lifetime detection test for an organic light-emitting device one with an electron injection layer of a single-layer structure in the related art and the organic light-emitting device two with the electron injection layer 130 of the single-layer structure in this embodiment. In this lifetime detection test, current densities supplied to the organic light-emitting device one and the organic light-emitting device two during the test are both 11.1 mA/cm². In this lifetime detection test, the material of the electron injection layer in the organic light-emitting device one in the related art includes only ytterbium, and a total thickness of the electron injection layer in the organic light-emitting device one in the related art is 20 Å; and the material of the electron injection layer 130 in the organic light-emitting device two of this embodiment includes ytterbium and lithium fluoride, a mass ratio of the ytterbium to the lithium fluoride is 1:1, and a total thickness of the electron injection layer 130 in the organic light-emitting device two of this embodiment is also 20 Å. In this lifetime detection test, the experimental results in Table 1 are obtained based on a plurality of organic light-emitting devices one having the same structure and a plurality of organic light-emitting devices two having the same structure. In this lifetime detection test, the test is conducted with organic light-emitting devices one and organic light-emitting devices two that are both light-emitting devices emitting blue light.

TABLE 1

| | Material of the | Lifetime | Voltage | Blue light |
|---|---|---|---|---|
| Classification | electron injection layer | (H) | (V) | index |
| Organic | Ytterbium | 390 | 4.36 | Reference |
| light-emitting | | | | |
| device one | | | | |
| Organic | Ytterbium:Lithium | 525 | 4.47 | Constant |
| light-emitting | fluoride = 1:1 | | | |
| device two | | | | |

As can be seen from Table 1, when the mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 is 1:1, on the premise that test conditions are same, a blue light index of the organic light-emitting device two is constant. Moreover, since the light-emitting efficiency of the organic light-emitting device is positively correlated with the blue light index of the organic light-emitting device, the light-emitting efficiency of the organic light-emitting device two in this embodiment is not affected. At the same time, the lifetime of the organic light-emitting device two is increased to 525 hours relative to the lifetime of the organic light-emitting device one of 390 hours. Therefore, when the mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 is 1:1, the service life of the organic light-emitting device is prolonged.

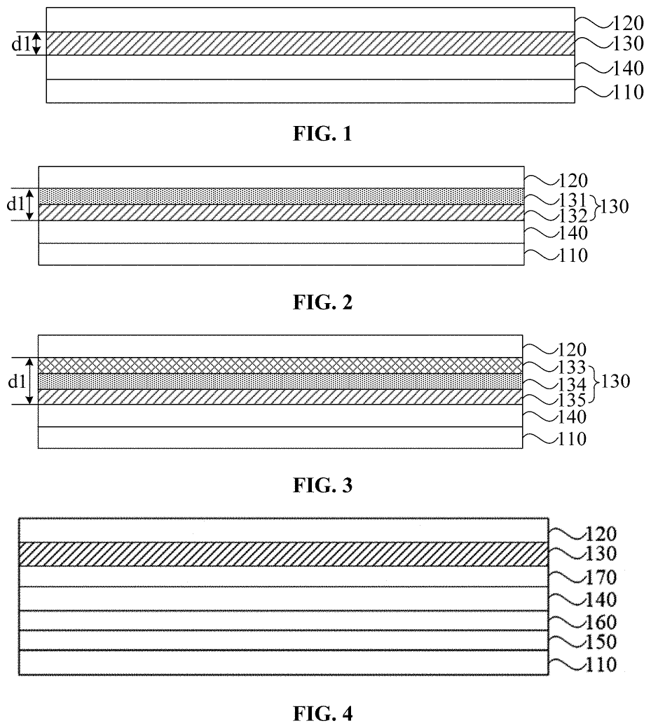

FIG. 2 is a structural diagram of another organic light-emitting device according to an embodiment of the present application. Referring to FIG. 2, the electron injection layer 130 includes at least two electron injection sub-layers arranged in a stack, and the at least two electron injection sub-layers include at least two types of the following three types of electron injection sub-layers: a electron injection sub-layer whose the material includes only ytterbium; a electron injection sub-layer whose the material includes the at least one of lithium fluoride, 8-hydroxyquinolinolato-lithium, lithium nitride, cesium fluoride, and cesium carbonate; and a electron injection sub-layer whose the material includes ytterbium and at least one of lithium fluoride, 8-hydroxyquinolinolato-lithium, lithium nitride, cesium fluoride, and cesium carbonate.

In one embodiment, the electron injection layer 130 includes at least two electron injection sub-layers arranged in a stack, and the at least two electron injection sub-layers include at least two types of the above-mentioned three types of electron injection sub-layers. In this manner, the material of the electron injection layer 130 composed of at least two electron injection sub-layers includes both the ytterbium and at least one of the lithium fluoride, the 8-hydroxyquinolinolato-lithium, the lithium nitride, the cesium fluoride, and the cesium carbonate. Therefore, the electron injection capability of the electron injection layer 130 can be ensured, and the oxidation of the ytterbium in the electron injection layer 130 can be inhibited, thereby prolonging the service life of the organic light-emitting device. Moreover, when the electron injection sub-layer is the electron injection sub-layer whose the material includes the ytterbium and the at least one of the lithium fluoride, the 8-hydroxyquinolinolato-lithium, the lithium nitride, the cesium fluoride, and the cesium carbonate, a mass ratio of the ytterbium in the material of the electron injection sub-layer to the at least one of the lithium fluoride, the 8-hydroxyquinolinolato-lithium, the lithium nitride, the cesium fluoride, and the cesium carbonate in the material of the electron injection sub-layer may refer to the mass ratio of the ytterbium in the material of the electron injection layer 130 to the at least one of the lithium fluoride, the 8-hydroxyquinolinolato-lithium, the lithium nitride, the cesium fluoride, and the cesium carbonate in the material of the electron injection layer 130 in a case where the electron injection layer 130 is the single-layer structure according to the above-mentioned embodiment of the present application.

Referring to FIG. 2, FIG. 2 schematically illustrates a case where the electron injection layer 130 includes two electron injection sub-layers (for example, the two electron injection sub-layers are denoted as a first electron injection sub-layer 131 and a second electron injection sub-layer 132). In FIG. 2, the two electron injection sub-layers may be any two types of the above-mentioned three types of electron injection sub-layers.

Table 2 shows two groups of test results obtained from a lifetime detection test for the organic light-emitting device one with the electron injection layer of the single-layer structure in the related art and the organic light-emitting device three with two electron injection sub-layers in this embodiment. In this lifetime detection test, current densities supplied to the organic light-emitting device one and the organic light-emitting device three during the test are both 11.1 mA/cm². In this lifetime detection test, the material of the electron injection layer in the organic light-emitting device one in the related art includes only ytterbium, and the total thickness of the electron injection layer in the organic light-emitting device one in the related art is 20 Å; and the material of one electron injection sub-layer of the two electron injection sub-layers in the organic light-emitting device three of this embodiment includes only ytterbium, the material of the other electron injection sub-layer in the organic light-emitting device three of this embodiment includes only lithium fluoride, a thickness of the electron injection sub-layer whose the material includes only the ytterbium is 10 Å, and a thickness of the electron injection sub-layer whose the material includes only the lithium fluoride is 10 Å, that is, the total thickness of the electron injection layer 130 in the organic light-emitting device three of this embodiment is also 20 Å. In this lifetime detection test, the experimental results in Table 2 are obtained based on a plurality of organic light-emitting devices one having the same structure and a plurality of organic light-emitting devices three having the same structure. In this lifetime detection test, the test is conducted with organic light-emitting devices one and organic light-emitting devices three that are both light-emitting devices emitting the blue light.

TABLE 2

| | Material of the electron | Lifetime | Voltage | Blue light |
|---|---|---|---|---|
| Classification | injection layer | (H) | (V) | index |
| Organic | Single structure including | 390 | 4.36 | Reference |
| light-emitting | only the material | | | |
| device one | ytterbium | | | |
| Organic | One electron injection | 455 | 4.43 | Slightly |
| light-emitting | sub-layer whose the | | | higher |
| device three | material is the ytterbium; | | | |
| | and the other electron | | | |
| | injection sub-layer whose | | | |
| | the material is the lithium | | | |
| | fluoride | | | |

As can be seen from the above-mentioned test data, when the electron injection layer 130 includes two electron injection sub-layers, the material of one electron injection sub-layer of the electron injection sub-layers includes only the ytterbium, and the material of the other electron injection sub-layer includes only the lithium fluoride, the service life of the organic light-emitting device is prolonged, and the blue light index of the organic light-emitting device is increased. Moreover, since the light-emitting efficiency of the organic light-emitting device is positively correlated with the blue light index of the organic light-emitting device, the light-emitting efficiency of the organic light-emitting device is also improved.

Still referring to FIG. 2, on the basis of the above-mentioned solution, in one embodiment, the electron injection layer 130 includes the first electron injection sub-layer 131 and the second electron injection sub-layer 132. The material of the first electron injection sub-layer 131 includes the ytterbium, and the material of the second electron injection sub-layer 132 includes the at least one of the lithium fluoride, the 8-hydroxyquinolinolato-lithium, the lithium nitride, the cesium fluoride, and the cesium carbonate. The second electron injection sub-layer 132 is disposed between the first electron injection sub-layer 131 and the light-emitting material layer 140.

In this embodiment, the second electron injection sub-layer 132 is disposed between the first electron injection sub-layer 131 and the light-emitting material layer 140, that is, the second electron injection sub-layer 132 is closer to the light-emitting material layer 140 relative to the first electron injection sub-layer 131. The material of the first electron injection sub-layer 131 includes the ytterbium, and the material of the second electron injection sub-layer 132 includes at least one of the lithium fluoride, the 8-hydroxyquinolinolato-lithium, the lithium nitride, the cesium fluoride, and the cesium carbonate. Therefore, the chemical property of the material of the second electron injection sub-layer 132 is more stable than the chemical property of the material of the first electron injection sub-layer 131. In this manner, even if the first electron injection sub-layer 131 is oxidized, since the second electron injection sub-layer 132 is closer to the light-emitting material layer 140, the second electron injection sub-layer 132 can still effectively inject electrons into the light-emitting material layer 140, thereby ensuring the electron injection capability of the electron injection layer 130.

FIG. 3 is a structural diagram of another organic light-emitting device according to an embodiment of the present application. Referring to FIG. 3, in one embodiment, the electron injection layer 130 includes a third electron injection sub-layer 133, a fourth electron injection sub-layer 134 and a fifth electron injection sub-layer 135 which are sequentially stacked from the second electrode 120 to the light-emitting material layer 140, a material of the third electron injection sub-layer 133 includes at least one of lithium fluoride, 8-hydroxyquinolinolato-lithium, lithium nitride, cesium fluoride, and cesium carbonate, a material of the fifth electron injection sub-layer 135 includes at least one of lithium fluoride, 8-hydroxyquinolinolato-lithium, lithium nitride, cesium fluoride, and cesium carbonate, and a material of the fourth electron injection sub-layer 134 includes ytterbium.

In this embodiment, the material included in the third electron injection sub-layer 133 and the material included in the fifth electron injection sub-layer 135 are stable in chemical properties, and the material included in the fourth electron injection sub-layer 134 is active in chemical properties. Therefore, the fourth electron injection sub-layer 134 is disposed between the third electron injection sub-layer 133 and the fifth electron injection sub-layer 135 such that the third electron injection sub-layer 133 and the fifth electron injection sub-layer 135 play a role in protecting the fourth electron injection sub-layer 134. For example, the third electron injection sub-layer 133 can inhibit the oxidation of the fourth electron injection sub-layer 134 by oxygen intruding from the second electrode 120 side, and the fifth electron injection sub-layer 135 can inhibit the oxidation of the fourth electron injection sub-layer 134 by oxygen intruding from the first electrode 110 side, thereby ensuring the electron injection capability of the entire electron injection layer 130, prolonging the service life of the organic light-emitting device, and ensuring the light-emitting efficiency of the organic light-emitting device.

Still referring to FIGS. 1 to 3, on the basis of the above-mentioned solution, in one embodiment, the total thickness dl of the electron injection layer 130 is 5 Å to 10 Å.

In this embodiment, when the electron injection layer 130 is the single-layer structure shown in FIG. 1, the total thickness dl of the electron injection layer 130 is the thickness of the electron injection layer 130 of the single-layer structure. When the electron injection layer 130 is a structure including a plurality of electron injection sub-layers shown in FIGS. 2 and 3, the total thickness dl of the electron injection layer 130 is a sum of thicknesses of the plurality of electron injection sub-layers. In this embodiment, the total thickness dl of the electron injection layer 130 is set to be 5 Å to 50 Å such that the thickness of the organic light-emitting device is relatively thin, thereby facilitating the thinning of the organic light-emitting device.

FIG. 4 is a structural diagram of another organic light-emitting device according to an embodiment of the present application. Referring to FIG. 4, on the basis of the above-mentioned solution, in one embodiment, the organic light-emitting device may further include at least one of the following film structures: a hole injection layer 150 disposed between the first electrode 110 and the light-emitting material layer 140, a hole transport layer 160 disposed between the first electrode 110 and the light-emitting material layer 140, and an electron transport layer 170 disposed between the light-emitting material layer 140 and the electron injection layer 130.

In one embodiment, the organic light-emitting device includes both the hole injection layer 150 and the hole transport layer 160, and the hole injection layer 150 is disposed between the hole transport layer 160 and the first electrode 110.

FIG. 4 is a structural diagram of an organic light-emitting device including the hole injection layer 150, the hole transport layer 160, and the electron transport layer 170 disposed between the light-emitting material layer 140 and the electron injection layer 130. In this embodiment, the electron injection layer 130 may firstly inject electrons of the second electrode 120 into the electron transport layer 170, and then the electron transport layer 170 injects and transport electrons into the light-emitting material layer 140. The electron transport layer 170 can enhance the electron injection and transport capabilities. Similarly, the hole injection layer 150 may firstly inject holes of the first electrode 110 into the hole transport layer 160, and the hole transport layer 160 injects holes into the light-emitting material layer 140 and transports the holes. The hole transport layer 160 can enhance the hole injection and transport capabilities.

When the organic light-emitting device includes only the hole injection layer 150 or the hole transport layer 160, the hole injection layer 150 or the hole transport layer 160 directly injects holes of the first electrode 110 into the light-emitting material layer 140.

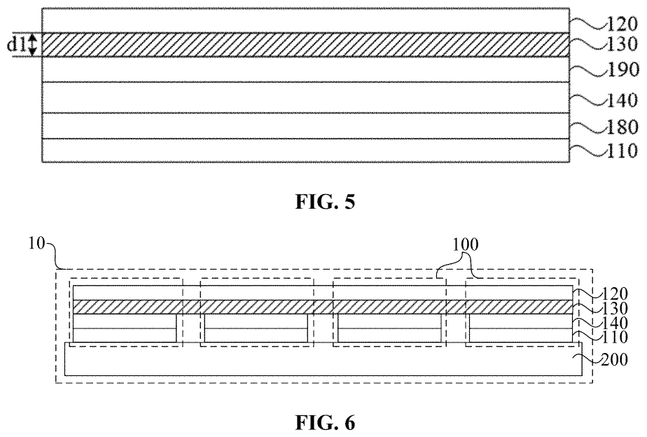

In one embodiment, as shown in FIG. 5, the organic light-emitting device may further include an electron blocking layer 180 at the first electrode 110 side and proximate to the light-emitting material layer 140, and a hole blocking layer 190 at the second electrode 120 side and proximate to the light-emitting material layer 140.

An embodiment of the present application further provides a display panel. FIG. 6 is a structural diagram of a display panel according to an embodiment of the present application. Referring to FIG. 6, the display panel 10 includes a plurality of organic light-emitting devices 100 provided by any one of the above-mentioned embodiments of the present application. The plurality of organic light-emitting devices 100 may be formed on a substrate 200, electron injection layers 130 of the plurality of organic light-emitting devices 100 may be interconnected as an integral layer, and second electrodes 120 of the plurality of organic light-emitting devices may be interconnected as an integral layer.

What is claimed is:

1. An organic light-emitting device, comprising:
a first electrode;
a second electrode;
an electron injection layer disposed between the first electrode and the second electrode; and
a light-emitting material layer disposed between the first electrode and the second electrode, wherein the electron injection layer is disposed between the second electrode and the light-emitting material layer, and a material of the electron injection layer comprises ytterbium and further comprises at least one of lithium fluoride, 8-hydroxyquinolinolato-lithium, lithium nitride, cesium fluoride, or cesium carbonate.

2. The organic light-emitting device of claim 1, wherein the electron injection layer is a single layer structure.

3. The organic light-emitting device of claim 2, wherein a mass ratio of the ytterbium of the material of the electron injection layer to the at least one of the lithium fluoride, the 8-hydroxyquinolinolato-lithium, the lithium nitride, the cesium fluoride, or the cesium carbonate of the material of the electron injection layer ranges from 1:10 to 10:1.

4. The organic light-emitting device of claim 3, wherein the mass ratio of the ytterbium of the material of the electron injection layer to the at least one of the lithium fluoride, the 8-hydroxyquinolinolato-lithium, the lithium nitride, the cesium fluoride, or the cesium carbonate of the material of the electron injection layer is 1:1.

5. The organic light-emitting device of claim 1, wherein the electron injection layer comprises at least two electron injection sub-layers arranged in a stack, and the at least two electron injection sub-layers comprise at least two types of the following three types of electron injection sub-layers:
a electron injection sub-layer whose a material comprises only ytterbium;
a electron injection sub-layer whose a material comprises at least one of lithium fluoride, 8-hydroxyquinolinolato-lithium, lithium nitride, cesium fluoride, or cesium carbonate; or
a electron injection sub-layer whose a material comprises ytterbium and at least one of lithium fluoride, 8-hydroxyquinolinolato-lithium, lithium nitride, cesium fluoride, or cesium carbonate.

6. The organic light-emitting device of claim 5, wherein the at least two electron injection sub-layers comprise a first electron injection sub-layer and a second electron injection sub-layer, a material of the first electron injection sub-layer comprises ytterbium, a material of the second electron injection sub-layer comprises at least one of lithium fluoride, 8-hydroxyquinolinolato-lithium, lithium nitride, cesium fluoride, or cesium carbonate, and the second electron injection sub-layer is disposed between the first electron injection sub-layer and the light-emitting material layer.

7. The organic light-emitting device of claim 5, wherein the at least two electron injection sub-layers comprise a third electron injection sub-layer, a fourth electron injection sub-layer and a fifth electron injection sub-layer which are sequentially stacked from the second electrode to the light-emitting material layer, a material of the third electron injection sub-layer comprises at least one of lithium fluoride, 8-hydroxyquinolinolato-lithium, lithium nitride, cesium fluoride, or cesium carbonate, a material of the fifth electron injection sub-layer comprises at least one of lithium fluoride, 8-hydroxyquinolinolato-lithium, lithium nitride, cesium fluoride, or cesium carbonate, and a material of the fourth electron injection sub-layer comprises ytterbium.

8. The organic light-emitting device of claim 1, wherein a total thickness of the electron injection layer ranges from 5 Å to 50 Å.

9. The organic light-emitting device of claim 1, further comprising at least one of the following film structures:
a hole injection layer disposed between the first electrode and the light-emitting material layer;
a hole transport layer disposed between the first electrode and the light-emitting material layer; or
an electron transport layer disposed between the light-emitting material layer and the electron injection layer.

10. The organic light-emitting device of claim 9, wherein in a case where the organic light-emitting device comprises both the hole injection layer and the hole transport layer, the hole injection layer is disposed between the hole transport layer and the second electrode.

11. The organic light-emitting device of claim 9, wherein in a case where the organic light-emitting device comprises the electron transport layer, the electron injection layer is configured to inject electrons generated by the second electrode into the electron transport layer, and the electron transport layer is configured to inject electrons injected into the electron transport layer by the electron injection layer into the light-emitting material layer.

12. The organic light-emitting device of claim 10, wherein the hole injection layer is configured to inject holes generated by the first electrode into the hole transport layer, and the hole transport layer is configured to inject holes injected into the hole transport layer by the hole injection layer into the light-emitting material layer.

13. The organic light-emitting device of claim 9, wherein in a case where the organic light-emitting device comprises the hole injection layer and comprise no hole transport layer, the hole injection layer is configured to inject holes generated by the first electrode into the light-emitting material layer.

14. The organic light-emitting device of claim 9, wherein in a case where the organic light-emitting device comprises the hole transport layer and does not comprise the hole injection layer, the hole transport layer is configured to inject holes generated by the first electrode into the light-emitting material layer.

15. The organic light-emitting device of claim 1, further comprising:
an electron blocking layer disposed between the first electrode and the light-emitting material layer.

16. The organic light-emitting device of claim 1, further comprising:
a hole blocking layer disposed between the electron injection layer and the light-emitting material layer.

17. The organic light-emitting device of claim 1, wherein the first electrode is an anode and the second electrode is a cathode.

18. A display panel, comprising a plurality of organic light-emitting devices according to claim 1.

19. The display panel of claim 18, further comprising a substrate, wherein the plurality of organic light-emitting devices are disposed on the substrate.

20. The display panel of claim 18, wherein electron injection layers of the plurality of organic light-emitting devices are interconnected as an integral layer, and second electrodes of the plurality of organic light-emitting devices are interconnected as an integral layer.
